(19) United States
(12) Patent Application Publication
(10) Pub. No.: US 2026/0283013 A1
(43) Pub. Date: Sep. 17, 2026

(54) PACKAGE STRUCTURE AND METHOD OF FORMING THE SAME

(71) Applicant: Taiwan Semiconductor Manufacturing Company, Ltd., Hsinchu (TW)

(72) Inventors: Yu-Siang Lin, Hsinchu City (TW); Chia-Hung Liu, Hsinchu City (TW); Ming-Fa CHEN, Taichung City (TW)

(73) Assignee: Taiwan Semiconductor Manufacturing Company, Ltd., Hsinchu (TW)

(21) Appl. No.: 19/079,430

(22) Filed: Mar. 13, 2025

(51) Int. Cl. H01L 23/00; G02B 6/42; H01L 21/56; H01L 23/31; H01L 23/538; H01L 25/16

(52) U.S. Cl. CPC H10W 90/00; G02B 6/4206; H10W 74/012; H10W 74/141; H10W 74/15; H10W 70/611; H10W 72/01351; H10W 72/07304; H10W 72/07331; H10W 72/07353; H10W 72/334; H10W 90/401; H10W 90/724; H10W 90/733; H10W 90/734

(57) ABSTRACT

Provided is a package structure and a method of forming the same. The method includes bonding a first integrated circuit component onto an interposer, wherein the first integrated circuit component has a recess filled with a sacrificial material therein; forming an underfill layer on the interposer to laterally surround the first integrated circuit component; forming an encapsulant on the interposer to laterally encapsulate the underfill layer and the first integrated circuit component; removing a portion of the encapsulant to expose the sacrificial material within the recess of the first integrated circuit component; and removing the sacrificial material to expose the recess of the first integrated circuit component.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a process flow for forming a package structure in accordance with some embodiments.

FIG. 2 to FIG. 4 illustrate cross-sectional views of intermediate stages in the formation of a package structure in accordance with some embodiments.

FIG. 5 illustrates a cross-sectional view of an integrated circuit component in accordance with some embodiments.

FIG. 6 illustrates a cross-sectional view of an integrated circuit component in accordance with some alternative embodiments.

FIG. 7 illustrates a cross-sectional view of an integrated circuit component in accordance with some other embodiments.

FIG. 8A to FIG. 8P illustrate cross-sectional views of intermediate stages in the formation of a photonic engine including a photonic die in accordance with some embodiments.

FIG. 9 illustrates a process flow for forming a photonic engine in accordance with some embodiments.

FIG. 10 illustrates an enlarged cross-sectional view of a region of FIG. 2 in accordance with some embodiments.

FIG. 11A to FIG. 11D illustrate cross-sectional views of a package structure in accordance with various embodiments.

FIG. 12 illustrates a cross-sectional view of a package structure in accordance with some embodiments.

FIG. 13 illustrates an enlarged cross-sectional view of a region of FIG. 12 in accordance with some embodiments.

FIG. 14 illustrates a cross-sectional view of a package structure in accordance with some alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A package structure including a photonic engine and the method of forming the same are provided. In accordance with some embodiments of the present disclosure, in the formation of the package structure, the photonic engine has the facet trench filled with the sacrificial polymer to prevent the underfill and the molding material from covering the light transmission surface. After removing the sacrificial polymer by wet chemical, the light transmission surface of the photonic engine is exposed without any underfill and/or molding residue blocking the light transmission. As such, the light emitting problem for edge coupling can be solved, and the signal latency between components can be reduced.

In addition, in the formation of the photonic engine with the facet trench, a first etching process and a second etching process are performed, each forming a facet (sidewall) for the respective photonic engine. The second etching process may be performed in the trenches formed in the first etching process. By performed two etching processes, both of the first etching process and the second process may be performed with lower strength, and hence the sidewalls of the resulting photonic engine are smoother.

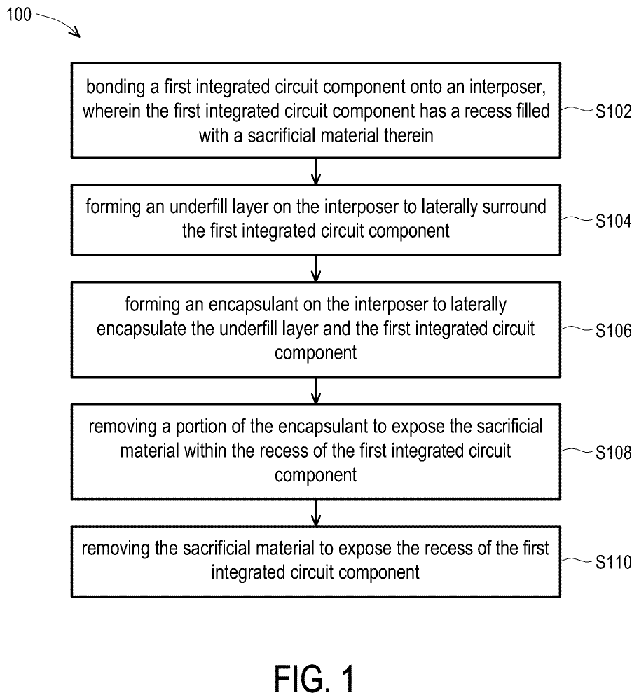

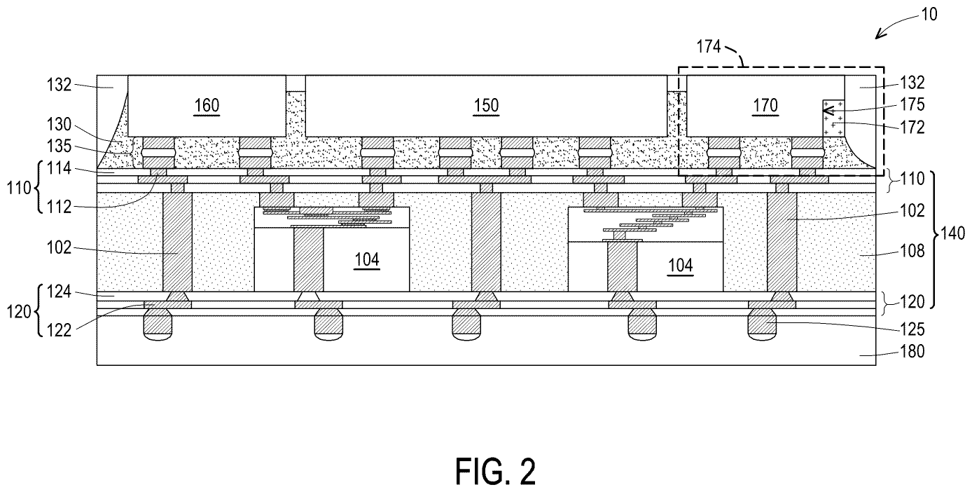

FIG. 2 to FIG. 5 illustrate cross-sectional views of intermediate stages in the formation of a package structure in accordance with some embodiments. The corresponding processes are also reflected schematically in the process flow shown in FIG. 1.

Referring to FIG. 2, an initial structure 10 is formed. In some embodiments, the initial structure 10 includes a plurality of integrated circuit components 150, 160 and 170, an interposer 140, an underfill layer 130, and an encapsulant 132. The respective process is shown as steps S102, S104, S106 in the process flow 100 as shown in FIG. 1. The brief process for forming the initial structure 10 is discussed below.

First, the interposer 140 is formed. The interposer 140 may include one or more dies 104 vertically sandwiched between a first redistribution structure 110 and a second redistribution structure 110, one or more conductive vias 102 aside the dies 104, and an encapsulant 108 laterally encapsulating the dies 104 and the conductive vias 102. In some embodiments, one of the dies 104 may be a local silicon interconnect (LSI) die to interconnect at least two components of overlying integrated circuit components 150, 160, and 170, thereby allowing for greater die-to-die routing capacity. That is, compared with the conventional redistribution lines (RDLs), the LSI die may have the greater routing density and transmission speed to achieve good bandwidth (BW) scalability and chip miniaturization. In some alternative embodiments, the other of the dies 104 may be a dummy die, which can provide better warpage control to the package structure.

In some embodiments, the LSI die also has other functions other than interconnection. For example, the LSI die may have active and/or passive components, such as diodes, transistors, image sensors, capacitors, resistors, and so on. In some alternative embodiments, the LSI die includes a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The conductive vias 102 may be also referred to as through vias, through molding vias, or through encapsulant vias. As an example to form the conductive vias 102, a seed layer (not shown) is formed over a carrier. In some embodiments, the seed layer is a metal layer, which may be a single layer or a composite layer comprising a plurality of sub-layers formed of different materials. In a particular embodiment, the seed layer comprises a titanium layer and a copper layer over the titanium layer. The seed layer may be formed using, for example, PVD or the like. A photoresist is formed and patterned on the seed layer. The photoresist may be formed by spin coating or the like and may be exposed to light for patterning. The pattern of the photoresist corresponds to conductive vias. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form the conductive vias 102.

In some embodiments, the encapsulant 108 is formed to laterally encapsulate the dies 104 and the conductive vias 102. The encapsulant 108 may be a molding compound, epoxy, or the like. The encapsulant 108 may be formed by compression molding, transfer molding, or the like. The encapsulant 108 may be applied in liquid or semi-liquid form and then subsequently cured.

In some embodiments, the first redistribution structure 110 includes insulating layers 114 and metallization patterns 112 alternately disposed over the dies 104, the encapsulant 108, and the conductive vias 102. The insulating layers 114 may be formed of a photo-sensitive material (such as PBO, polyimide, BCB, or the like) or a non-photo-sensitive material (such as silicon oxide, silicon nitride, or the like). The insulating layers 114 may be formed by spin coating, lamination, CVD, the like, or a combination thereof, and may be patterned by exposing and developing processes or etching processes. The metallization patterns 112 may also be referred to as redistribution layers or redistribution lines. The metallization patterns 112 include metal lines and vias formed in one or more insulating layers 114. In some embodiments, the metallization patterns 112 may include a conductive material such as copper, silver, gold, tungsten, aluminum, combinations thereof, or the like, and may be formed through any acceptable process, such as a damascene process, a dual damascene process, or the like. In some embodiments, the first redistribution structure 110 may include any number of insulating layers and metallization patterns.

In some embodiments, the second redistribution structure 120 includes insulating layers 124 and metallization patterns 122 alternately disposed under the dies 104, the encapsulant 108, and the conductive vias 102. The insulating layers 124 may be formed of a photo-sensitive material (such as PBO, polyimide, BCB, or the like) or a non-photo-sensitive material (such as silicon oxide, silicon nitride, or the like). The insulating layers 124 may be formed by spin coating, lamination, CVD, the like, or a combination thereof, and may be patterned by exposing and developing processes or etching processes. The metallization patterns 122 may also be referred to as redistribution layers or redistribution lines. The metallization patterns 122 include metal lines and vias formed in one or more insulating layers 124. In some embodiments, the metallization patterns 122 may include a conductive material such as copper, silver, gold, tungsten, aluminum, combinations thereof, or the like, and may be formed through any acceptable process, such as a damascene process, a dual damascene process, or the like. In some embodiments, the second redistribution structure 120 may include any number of insulating layers and metallization patterns. In the present embodiment, the first redistribution structure 110 may be referred to as a frontside redistribution structure since the first redistribution structure 110 is adjacent to a frontside (or active surface) of the dies 104. In addition, the second redistribution structure 120 may be referred to as a backside redistribution structure since the second redistribution structure 120 is adjacent to a backside (or back surface) of the dies 104.

After forming the interposer 140, the integrated circuit components 150, 160 and 170 may be bonded onto the interposer 140. The respective process is shown as a step S102 in the process flow 100 as shown in FIG. 1. Specifically, the integrated circuit components 150, 160 and 170 are bonded to the first redistribution structure 110 by a plurality of conductive connectors 135. The integrated circuit components 150, 160 and 170 may have the same or different functions from each other, as discussed in detail below.

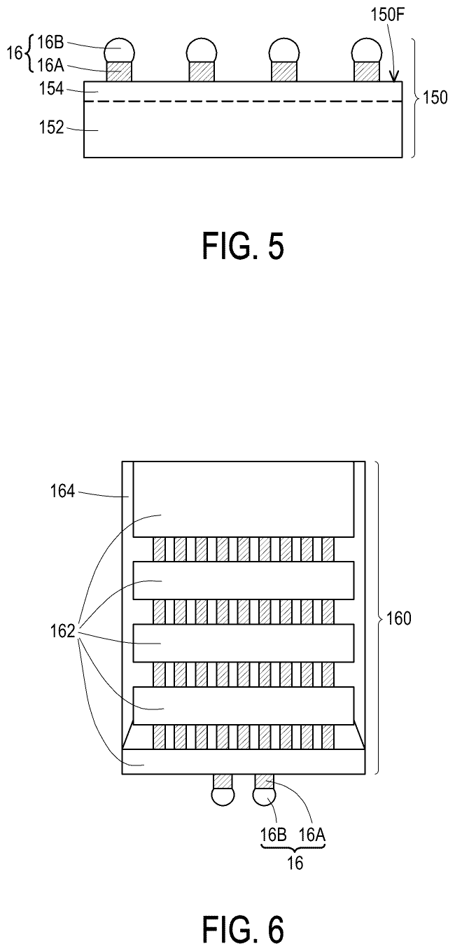

FIG. 5 illustrates a cross-sectional view of an exemplary integrated circuit component 150 in accordance with some embodiments. It is appreciated that the integrated circuit component 150 of FIG. 5 represents some of the possible structures of the integrated circuit component 150, but the embodiments of the present disclosure are not limited thereto. The integrated circuit component 150 will be packaged in subsequent processing to form integrated circuit packages. The integrated circuit component 150 may be a logic device (e.g., application-specific integrated circuit (ASIC) die, central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or a combination thereof (e.g., a system-on-a-chip (SoC) die). The integrated circuit component 150 may be formed in a wafer, which may include different die regions that are singulated in subsequent steps to form a plurality of integrated circuit components 150. The integrated circuit component 150 includes a semiconductor substrate 152, an interconnect structure 154, and electrical connectors 16.

The semiconductor substrate 152 may be a substrate of silicon, doped or undoped, or an active layer of a semiconductor-on-insulator (SOI) substrate. The semiconductor substrate 152 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 152 has an active or a front-side surface (e.g., the surface facing upward) and an inactive or a backside surface (e.g., the surface facing downward). Devices are at the active surface of the semiconductor substrate 152. The devices may be active devices (e.g., transistors, diodes, etc.) and/or passive devices (capacitors, resistors, inductors, etc.). The inactive surface may be free from devices.

The interconnect structure 154 is over the active surface of the semiconductor substrate 152, and is used to electrically connect the devices of the semiconductor substrate 152 to form an integrated circuit. The interconnect structure 154 may include one or more dielectric layer(s) and respective metallization layer(s) in the dielectric layer(s). Acceptable dielectric materials for the dielectric layers include low-k dielectric materials such as phospho-silicate glass (PSG), boro-silicate glass (BSG), boron-doped phospho-silicate glass (BPSG), undoped silicate glass (USG), or the like. Acceptable dielectric materials for the dielectric layers further include oxides such as silicon oxide or aluminum oxide; nitrides such as silicon nitride; carbides such as silicon carbide; the like; or combinations thereof such as silicon oxynitride, silicon oxycarbide, silicon carbonitride, silicon oxycarbonitride or the like. Other dielectric materials may also be used, such as a polymer such as polybenzoxazole (PBO), polyimide, a benzocyclobuten (BCB) based polymer, or the like. The metallization layers may include conductive vias and/or conductive lines to interconnect the devices of the semiconductor substrate 152. The metallization layers may be formed of a conductive material, such as a metal, such as copper, cobalt, aluminum, gold, combinations thereof, or the like. The interconnect structure 154 may be formed by a damascene process, such as a single damascene process, a dual damascene process, or the like.

A plurality of electrical connectors 16 are formed at a frontside 150F of the integrated circuit component 150. The electrical connectors 16 may comprise metal pillars 16A and solder regions 16B over the metal pillars 16A. In some embodiments, the metal pillars 16A may be formed by forming a seed layer over the interconnect structure 154. The seed layer may be a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metal pillars 16A. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, nickel, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the metal pillars 16A.

In some embodiments, the metal pillars 16A may be referred to as under-bump metallizations (UBMs), which may include three layers of conductive materials, such as a layer of titanium, a layer of copper, and a layer of nickel. Other arrangements of materials and layers, such as an arrangement of copper/nickel/copper, an arrangement of chrome/chrome-copper alloy/copper/gold, an arrangement of titanium/titanium tungsten/copper, or an arrangement of copper/nickel/gold, may be utilized for the formation of the UBMs 16A. Any suitable materials or layers of material that may be used for the UBMs 16A are fully intended to be included within the scope of the current application.

The solder regions 16B may comprise a solder material and may be formed over the metal pillars 16A by dipping, printing, plating, or the like. The solder material may comprise, for example, lead-based and lead-free solders, such as Pb-Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free solders may further include SnCu compounds as well, without the use of silver (Ag). Lead-free solders may also include tin and silver, Sn-Ag, without the use of copper. In some embodiments, a reflow process may be performed, giving the solder regions 16B a shape of a partial sphere in some embodiments. In other embodiments, the solder regions 16B may have other shapes, such as non-spherical shapes.

In some embodiments, the solder regions 16B may be used to perform chip probe (CP) testing on the integrated circuit component 150. For example, the solder regions may be solder balls, solder bumps, or the like, which are used to attach a chip probe to the electrical connectors 16. Chip probe testing may be performed on the integrated circuit component 150 to ascertain whether the integrated circuit component 150 is a known good die (KGD). Thus, only integrated circuit components 150, which are KGDs, undergo subsequent processing and are packaged, and dies which fail the chip probe testing are not packaged. In some embodiments, after testing, the solder regions 16B may be removed in subsequent processing steps.

FIG. 6 illustrates a cross-sectional view of an exemplary integrated circuit component 160 in accordance with some embodiments. It is appreciated that the integrated circuit component 160 of FIG. 6 represents some of the possible structures of the integrated circuit component 160, but the embodiments of the present disclosure are not limited thereto. The integrated circuit component 160 is a stacked device that includes multiple semiconductor substrates 162 and an encapsulant 164 encapsulating the semiconductor substrates 162. For example, the integrated circuit component 160 may be a memory device that includes multiple memory dies such as a hybrid memory cube (HMC) device, a high bandwidth memory (HBM) device, or the like. In such embodiments, the integrated circuit component 160 includes multiple semiconductor substrates 162 interconnected by through-substrate vias (TSVs) such as through-silicon vias (not shown). Each of the semiconductor substrates 162 may (or may not) have a separate interconnect structure.

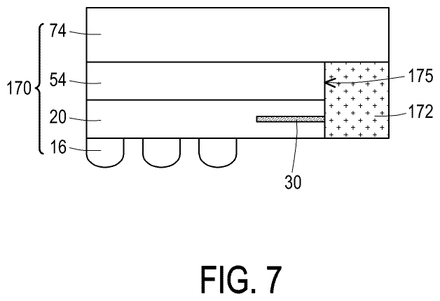

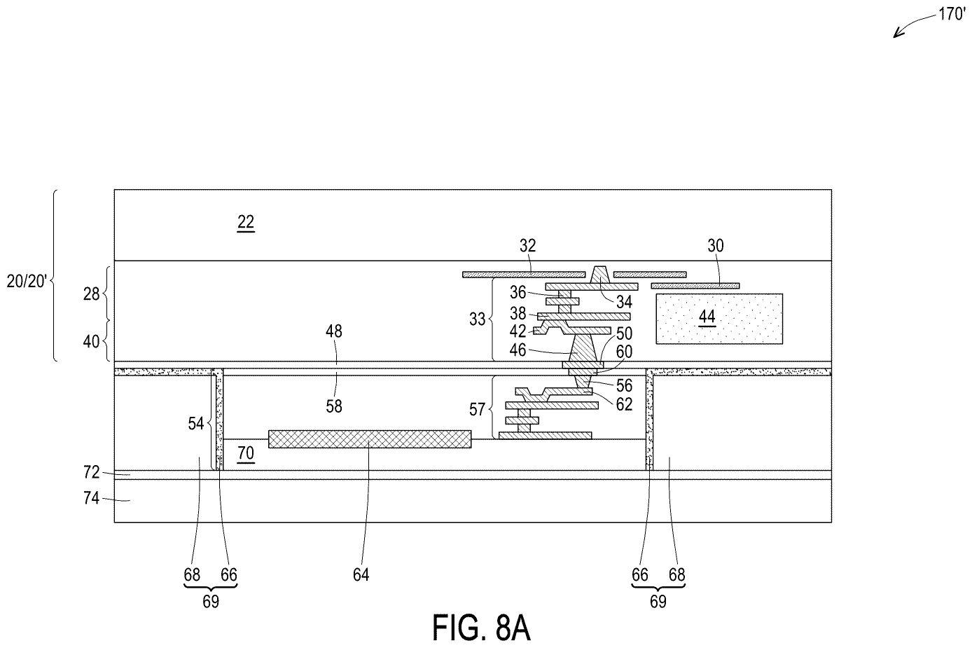

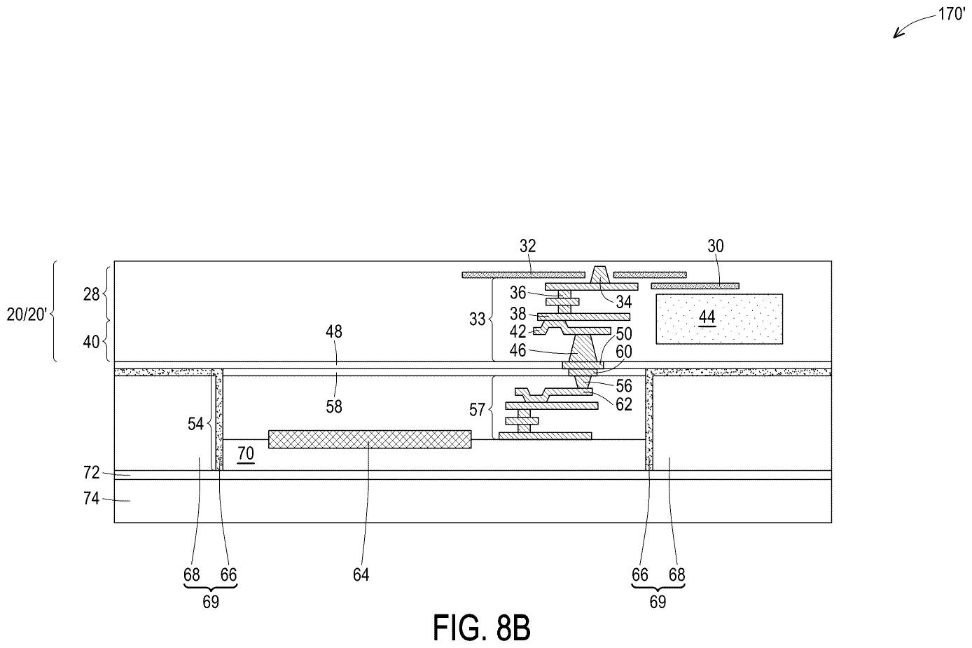

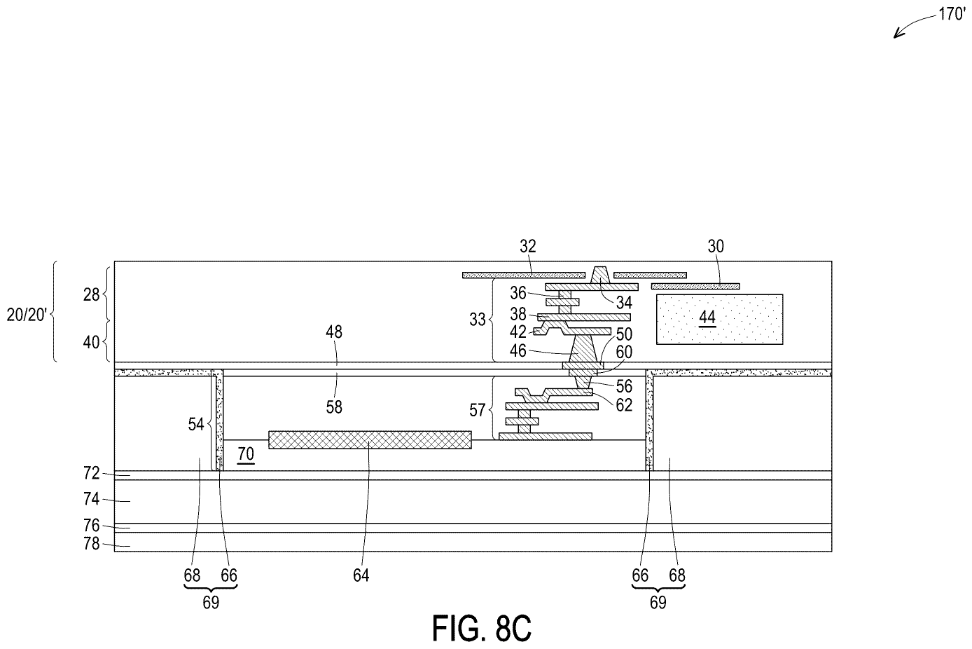

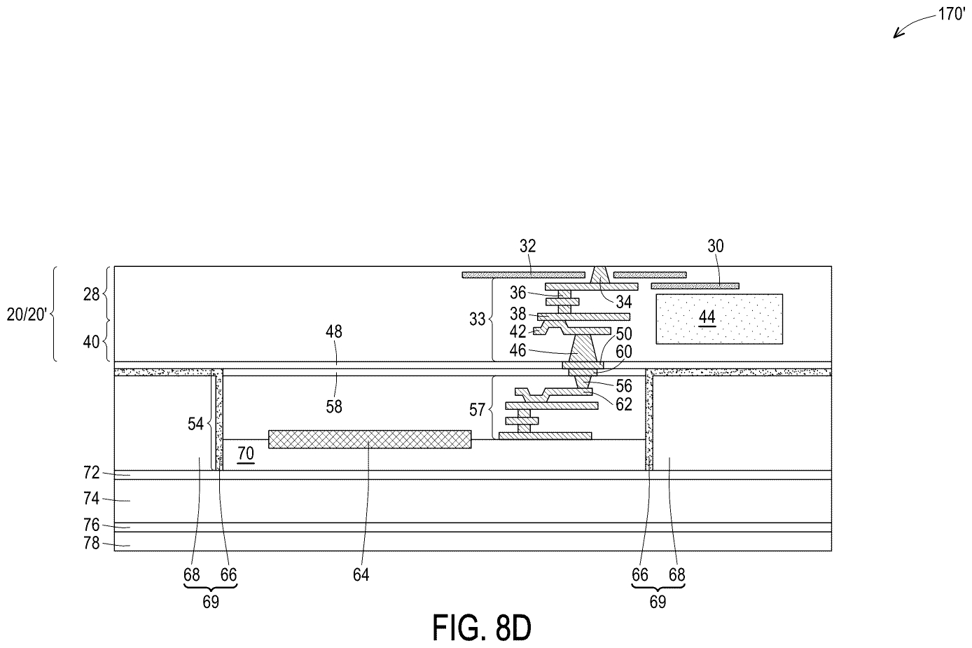

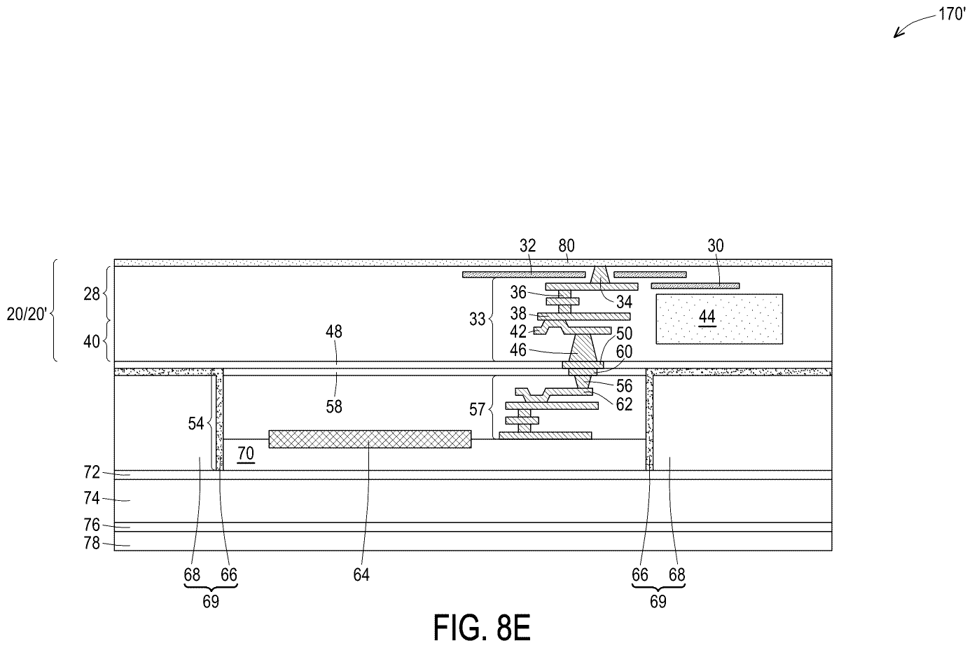

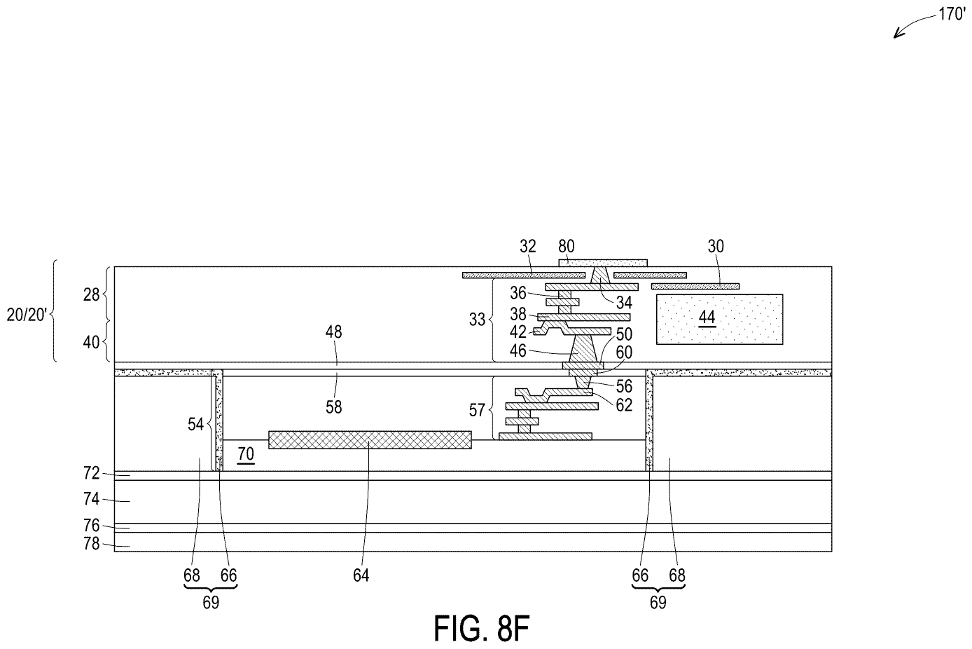

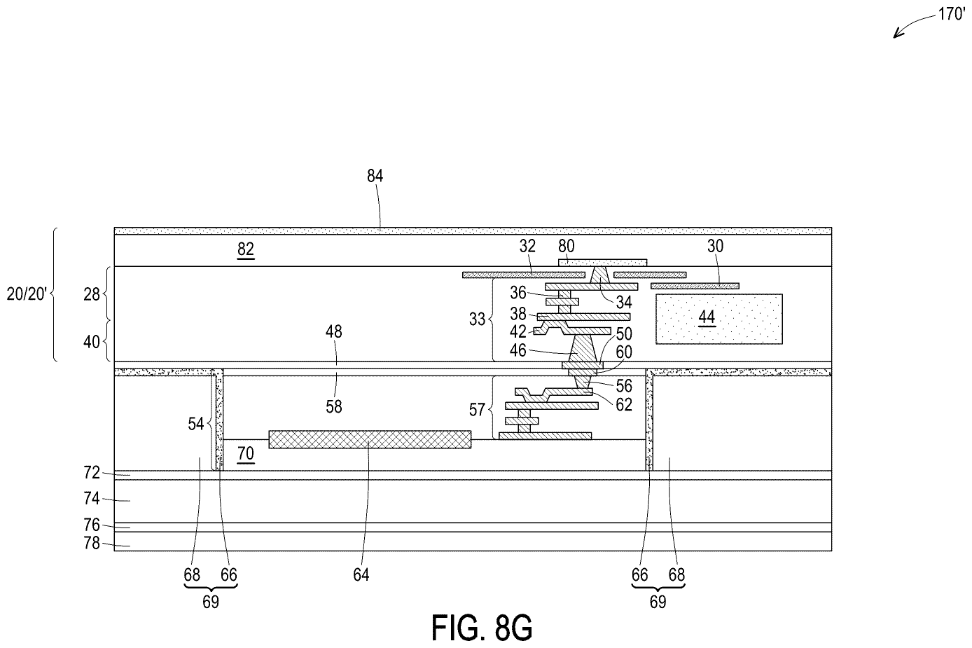

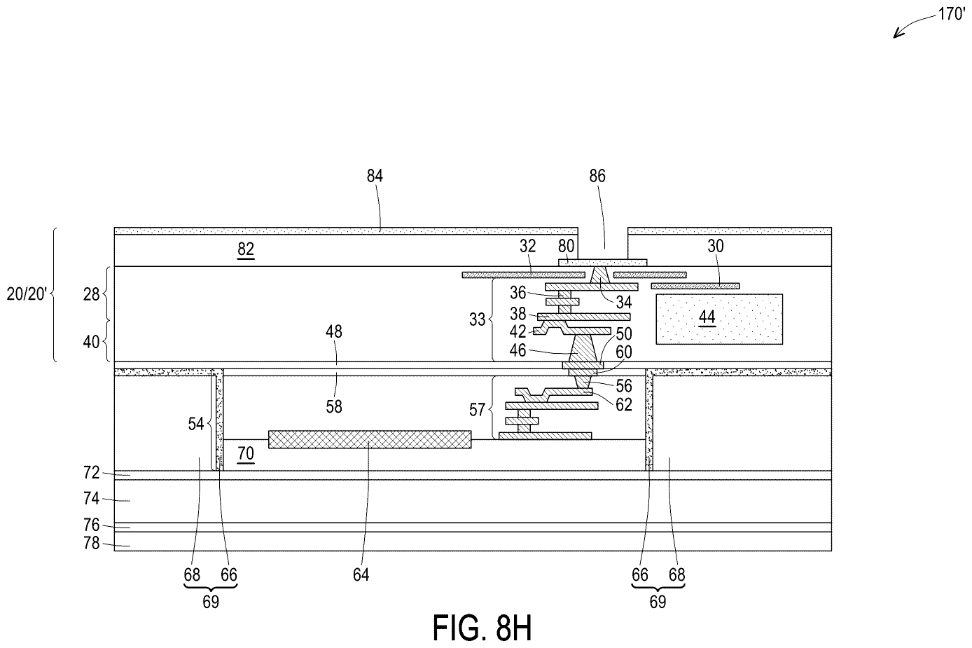

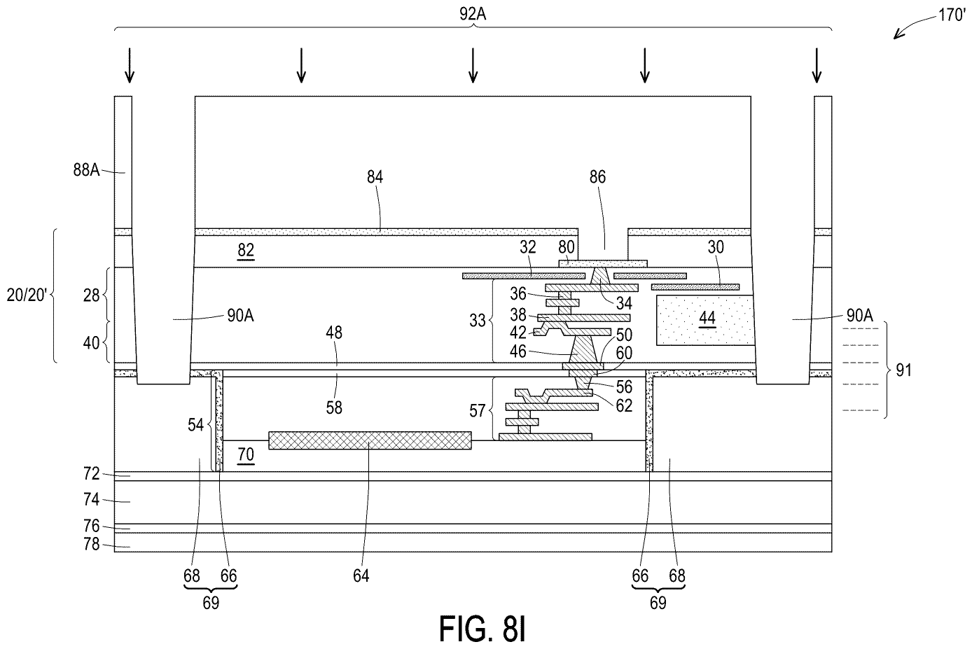

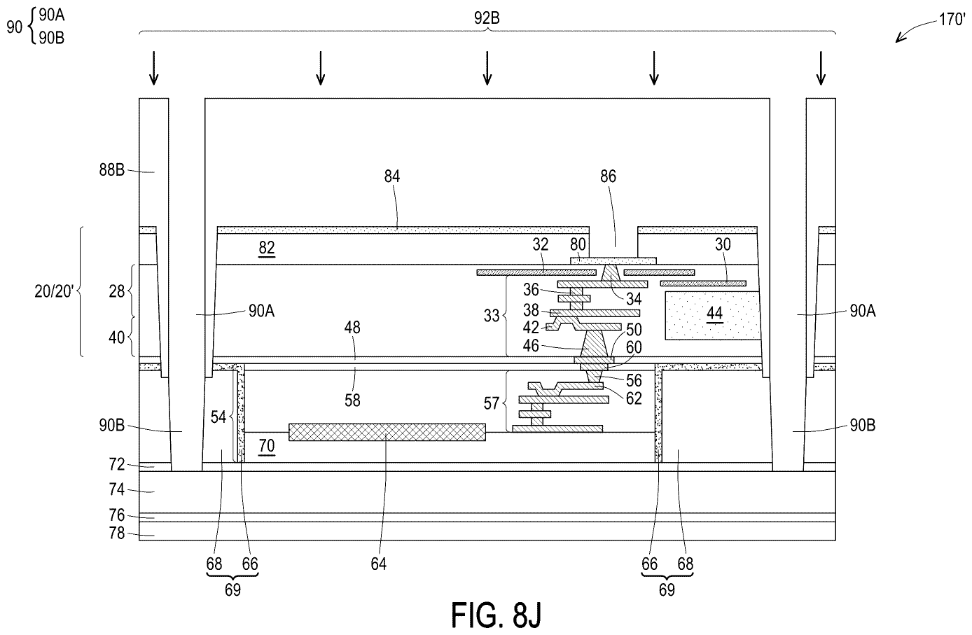

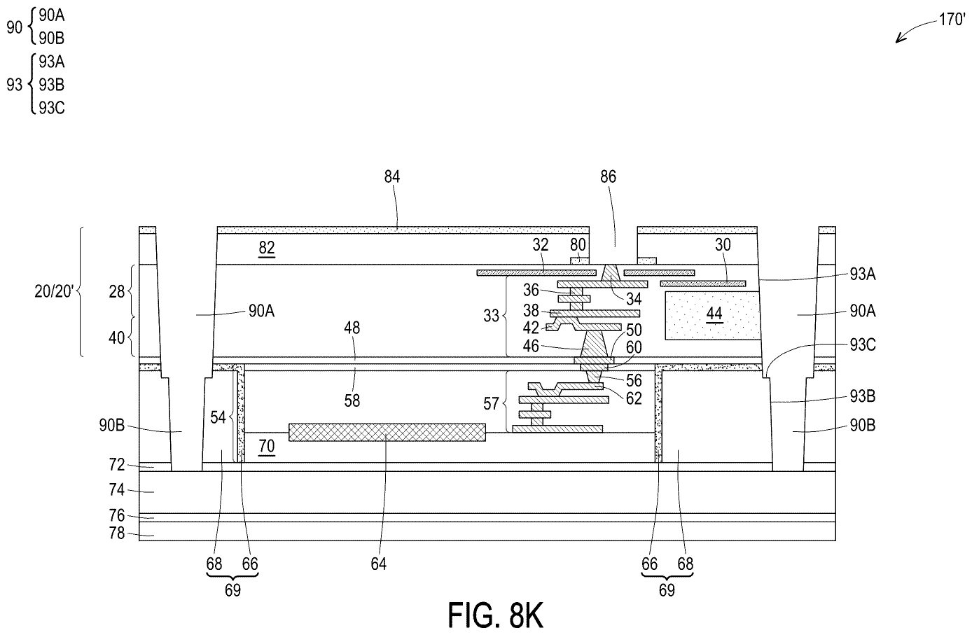

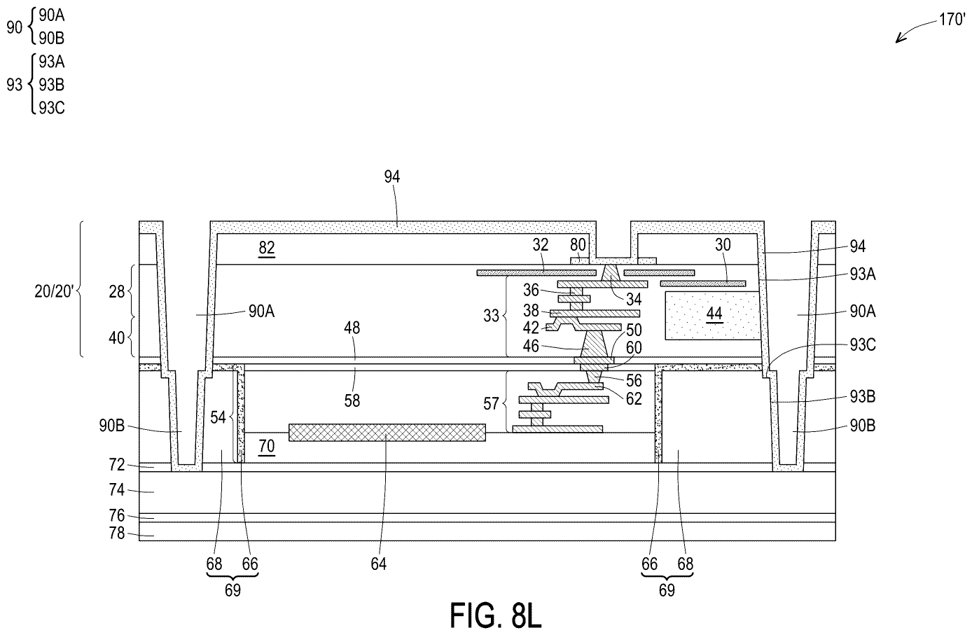

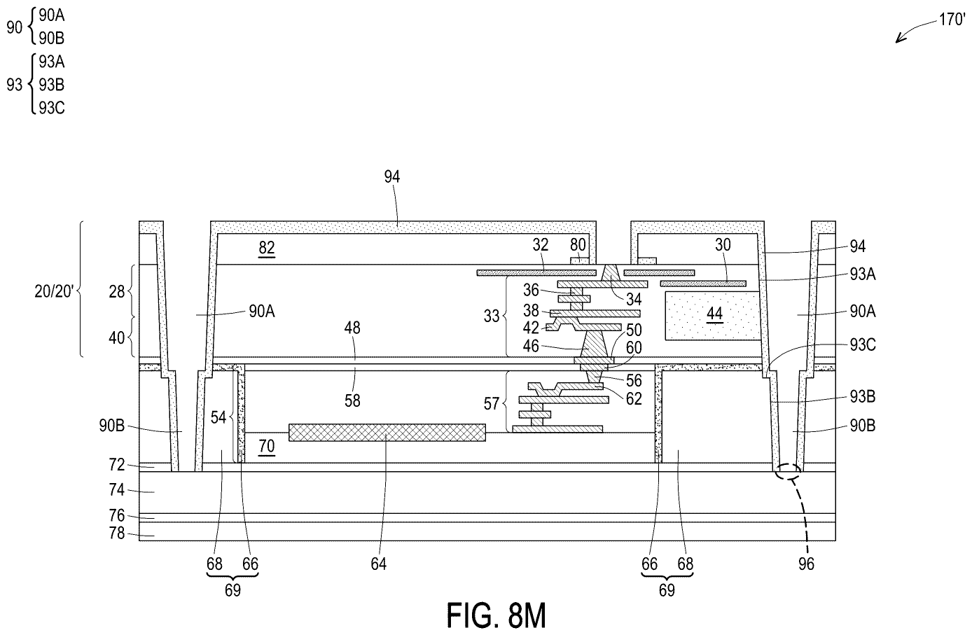

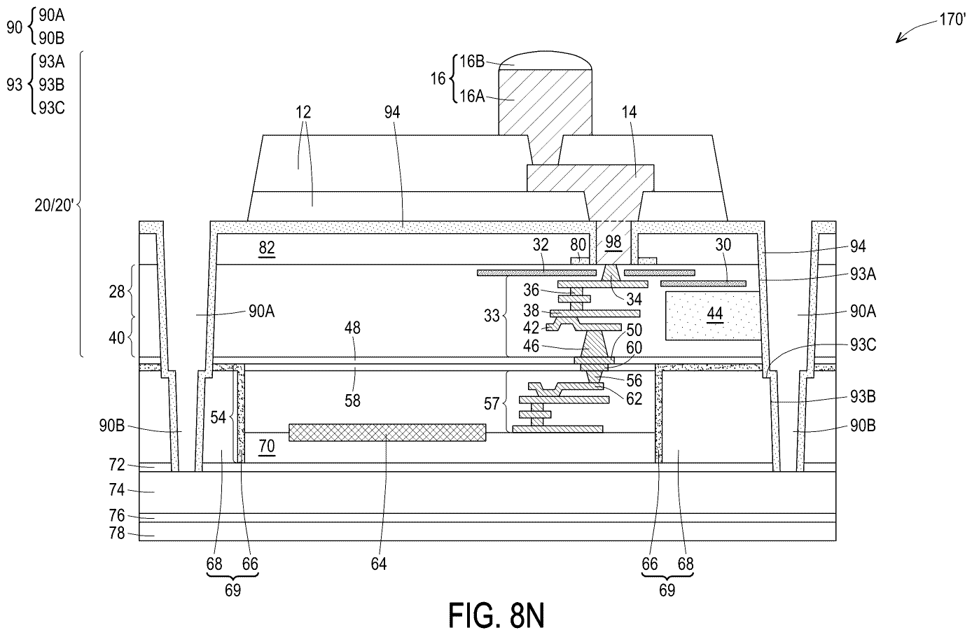

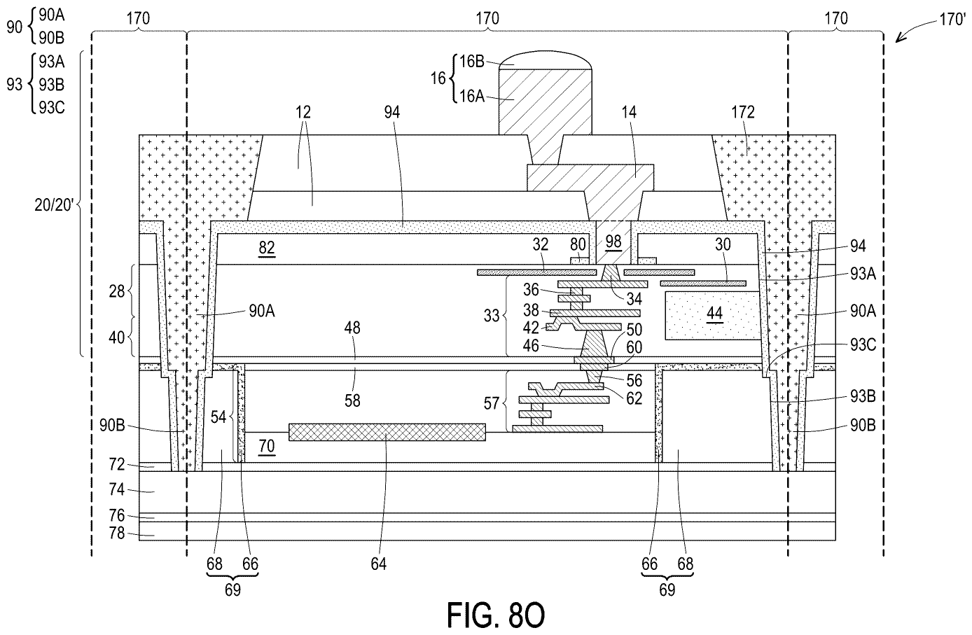

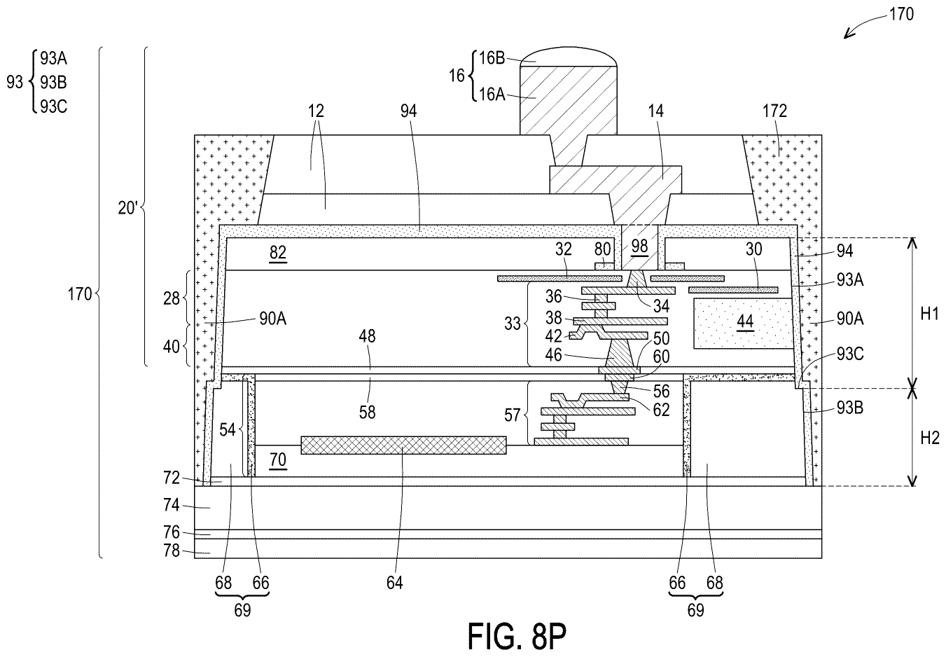

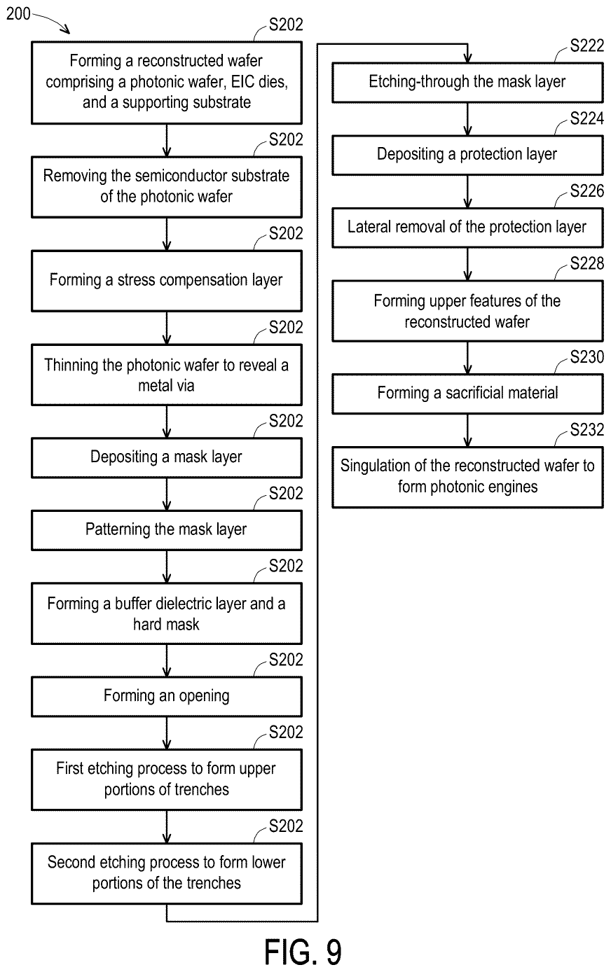

FIG. 7 illustrates a cross-sectional view of an exemplary integrated circuit component 170 in accordance with some embodiments. It is appreciated that the integrated circuit component 170 of FIG. 7 represents some of the possible structures of the integrated circuit component 170, but the embodiments of the present disclosure are not limited thereto. In some embodiments, the integrated circuit component 170 may be an optical integrated circuit chip, such as an optical engine. The integrated circuit component 170 may include an electrical integrated circuit (EIC) 54 bonded to a photonic integrated circuit (PIC) 20, and a supporting substrate 74 over the EIC 54. As shown in FIG. 7, the supporting substrate 74 may protrude from the sidewall of the stack structure including the EIC 54 and the PIC 20 to form a lateral recess 175, and a sacrificial material 172 may be formed within the recess 175 to protect the light transmission surface adjacent to the waveguide 30. FIG. 8A to FIG. 8P illustrate cross-sectional views of intermediate stages in the formation of a photonic engine 170 including a photonic die 20 in accordance with some embodiments. The corresponding processes are also reflected schematically in the process flow shown in FIG. 9.

Referring to FIG. 8A, a reconstructed wafer 170′ is formed, which includes a photonic wafer 20′, one or more electronic dies 54 and a supporting substrate 74. The respective process is shown as a step S202 in the process flow 200 as shown in FIG. 9. The brief process for forming reconstructed wafer 170′ is discussed below.

The photonic wafer 20′ is first formed. In accordance with some embodiments, the photonic wafer 20′ comprises a plurality of photonic dies 20 that are identical to each other. The Photonic dies 20 may also be referred to as photonic Integrated circuit (PIC) dies.

The photonic die 20 may include a semiconductor substrate 22, which may be a silicon wafer in accordance with some embodiments. The photonic die 20 may include photonic devices such as waveguides, grating couplers, modulators, and/or the like. In accordance with some embodiments, the photonic die 20 may include waveguides 30 and 32. The waveguide 30 may be a nitride waveguide, which may be formed of silicon nitride. The waveguide 32 may be a silicon waveguide. The silicon waveguide 32 may be formed by bonding a silicon layer to an overlying dielectric layer 28, followed by the patterning of the silicon layer through etching, so that waveguides, grating couplers, and the like are formed. In accordance with some embodiments, the waveguide 30 is used for edge coupling, and is configured to receive optical signals from an optical fiber. The optical signal received by the waveguide 30 may be coupled to the silicon waveguide 32.

In accordance with some embodiments, dielectric layers 28 are formed on the semiconductor substrate 22, in which the photonic devices such as the waveguides 30 and 32 are formed. The dielectric layers 28 may comprise light-transparent and low-loss dielectric materials such as silicon oxide. The dielectric layers 28 may include a plurality of dielectric layers formed of different materials, which may include Inter-Metal Dielectric (IMDs) that may include a low-k dielectric material(s) such as porous silicon oxynitride. There may also be etch stop layers formed between the low-k dielectric materials. The etch stop layers may comprise AlN, AlO, SiON, or the like, or multi-layers thereof.

An interconnect structure 33 is formed, which may include vias 36 and metal lines 38 and the respective portions of the dielectric layers 28. The vias 36 and the metal lines 38 may be formed through single damascene processes and/or dual damascene processes. In accordance with some embodiments, the metal via 34 is formed to connect to the interconnect structure 33. The metal via 34 may be formed through a damascene process such as a single damascene process.

For example, the via 34, the vias 36, and the metal lines 38 may be formed through a single damascene process by forming openings in the dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material form the vias 34 and 36 and the metal lines 38.

A plurality of dielectric layers 40 are then formed. In accordance with some embodiments, some of the dielectric layers 40 may comprise inorganic dielectric materials such as silicon oxide, silicon nitride, silicon carbide, silicon oxynitride, or the like, which may form passivation layers. The corresponding dielectric layers may be formed through deposition processes, followed by a planarization process such as a Chemical Mechanical Polish (CMP) process or a mechanical grinding process. Some of dielectric layers 40 may be formed of or comprise an organic dielectric material(s), which may include a polymer(s) such as polyimide, polybenzoxazole (PBO), benzocyclobutene (BCB), or the like.

In accordance with some embodiments, metal pad(s) 42 are formed to electrically connect to the interconnect structure 33. Metal pads 42 may be formed of or comprise aluminum copper, copper, nickel, or the like, or multi-layers thereof. In accordance with some embodiments, the formation of the metal pads 42 may comprise depositing one of the passivation layers, forming openings in the corresponding passivation layer to expose the metal pads in the interconnect structure 33, depositing a metal layer that extends into the openings, and performing an etching process to etch the metal layer. The remaining portions of the metal layer form the metal pads 42.

In accordance with some embodiments, a bulk dielectric region 44 is formed under waveguide 30. In accordance with some embodiments, the bulk dielectric region 44 is a large dielectric block formed of a homogenous dielectric material. The bulk dielectric region 44 is close to and overlapped by the waveguide 30. The bulk dielectric region 44 is used to form a homogenous environment, so that the interference from the surrounding environment to the waveguide 30 is reduced. In accordance with some embodiments, the bulk dielectric region 44 is formed of or comprise silicon oxide, silicon oxynitride, silicon carbide, silicon oxycarbide, or the like, or other dielectric materials.

A conductive feature 46 such as a metal via is formed to electrically connect to the metal pad 42 and the metal lines 38. A bonding layer 48 is formed. In accordance with some embodiments, the bonding layer 48 may have a multi-layer structure or a single layer structure. The bonding layer 48 may comprise a silicon-containing dielectric material such as silicon oxide, silicon nitride, silicon carbide, silicon oxynitride, silicon oxycarbide, silicon oxycarbonitride or the like.

Bonding pads 50 are formed in the bonding layer 48. In accordance with some embodiments, the bonding pads 50 may comprise copper, and may comprise a diffusion barrier, such as Ti, TiN, Ta, TaN, or the like. The formation process may include etching bonding layer 48 to form openings, depositing a conductive material to fill the openings, and performing a planarization process to remove the portions of the conductive material over the bonding layer 48.

Further referring to FIG. 8A, the device die 54, which may be an Electronic Integrated circuit (EIC) die (also referred to as an electronic die) or another type of die such as an independent passive device die, an Integrated Voltage Regulator (IVR) die, or the like is bonded to the photonic die 20. Throughout the description, the die 54 is referred to as an EIC die 54.

In accordance with some embodiments, the EIC die 54 includes a semiconductor substrate 70 (which may be a silicon substrate) and the integrated circuit devices 64 formed on a surface of the semiconductor substrate 70. The integrated circuit devices 64 (which may include active devices such as transistors) are used to support the functionality of the photonic die in accordance with some embodiments. The integrated circuit devices 64 may also include passive devices such as capacitors, resistors, or the like. An interconnect structure 57 is formed in the EIC die 54, and to electrically connect to the integrated circuit devices 64.

In accordance with some embodiments, the integrated circuit devices 64 may include the integrated circuits for communicating with the photonic die 20, such as the circuits for controlling the operation of the photonic die 20. For example, the EIC die 54 may include controllers, drivers, amplifiers, and the like, and combinations thereof. the EIC die 54 may also include a Central Processing Unit (CPU). In accordance with some embodiments, the EIC die 54 includes the circuits for processing the electrical signals converted from the optical signals received from the photonic die 20, and/or the electrical signals to be converted to the optical signals that will be transmitted out of the photonic die 20. The EIC die 54 may also control high-frequency signaling of the photonic die 20 according to electrical signals (digital or analog) received from another device or die, in accordance with some embodiments. In accordance with some embodiments, the EIC die 54 may include a circuit that provides Serializer/Deserializer (SerDes) functionality. In this manner, the EIC die 54 may act as a part of an I/O interface between optical signals and electrical signals.

The EIC die 54 may include metal pad 62, via 56 connected to metal pad 62, and bonding pad 60 electrically connected to the via 56. The bonding pad 60 may be electrically connected to the integrated circuits in the EIC die 54.

The bonding between the photonic die 20 and the EIC die 54 may include metal-to-metal direct bonding, solder bonding, or hybrid bonding that includes both of metal-to-metal direct bonding and fusion bonding. For example, the bonding layer 58 is bonded to the bonding layer 48 through fusion bonding. The material of the bonding layer 58 may be the same or different from the material of the bonding layer 48.

It is appreciated that the structure as illustrated in FIG. 8A is at wafer level, wherein a plurality of identical EIC dies 54 may be bonded to a plurality of photonic dies 20 of the photonic wafer 20′ in accordance with some embodiments. A gap-fill process is performed in accordance with some embodiments, wherein the gaps between the EIC dies 54 are filled to form dielectric regions (that encircle the EIC dies 54), which are also referred to as gap-fill regions.

Further referring to FIG. 8A, after the bonding of the EIC dies 54 to the photonic dies 20, a dielectric barrier 66 is deposited. The deposition process includes a conformal deposition process such as Atomic Layer Deposition (ALD), Chemical Vapor Deposition (CVD), or the like. The material of the dielectric barrier 66 is selected to have good adhesion ability on the EIC dies 54. In accordance with some embodiments, the dielectric barrier 66 is formed of or comprise silicon nitride, silicon carbo-nitride, silicon oxynitride, silicon carbide, or the like.

A dielectric region 68 is then formed. In accordance with some embodiments, the formation process may include depositing a dielectric material, and performing a planarization process such as a CMP process or a mechanical grinding process on the deposited dielectric material. The planarization process may use the semiconductor substrate 70 as a CMP stop layer. The dielectric material of the dielectric region 68 may comprise silicon oxide, silicon oxynitride, or the like, which material may be different from the material of the dielectric barrier 66. The dielectric barrier 66 and the dielectric region 68 are collectively referred to as gap-fill regions 69.

A bonding layer (an upper portion of the illustrated bonding layer 72) is then formed on the semiconductor substrate 70 and the gap-fill regions 69, for example, through a deposition process. In accordance with some embodiments, the bonding layer is formed of or comprise silicon oxide, silicon nitride, silicon carbide, silicon oxynitride, silicon oxycarbide, silicon oxycarbonitride, or the like.

The supporting substrate 74 (which may be a wafer) is bonded to bonding layer 72. In accordance with some embodiments, supporting substrate 74 comprises a silicon substrate (a silicon wafer). There may be another bonding layer pre-formed on supporting substrate 74 before the bonding, and the bonding layer formed on the EIC dies 54 and the gap-fill regions 69 is bonded to the bonding layer pre-formed on the semiconductor substrate 74 to form the bonding layer 72. The bonding may include fusion bonding.

Throughout the description, the structure shown in FIG. 8A is referred to as a reconstructed wafer 170'. In subsequent processes as shown in FIG. 8A through FIG. 8O, further processes are performed on the reconstructed wafer 170′ to form more features.

The semiconductor substrate 22 of the photonic wafer 20′ is then removed, and the resulting structure is shown as shown in FIG. 8B. The respective process is shown as a step S204 in the process flow 200 as shown in FIG. 9. In accordance with some embodiments, the removal of the semiconductor substrate 22 may comprise a CMP process, a mechanical grinding process, or the like. The dielectric layer 28 is thus exposed. In accordance with alternative embodiments in which the photonic die 20 include active devices, the semiconductor substrate 22 may remain.

Referring to FIG. 8C, a stress compensation layer 78 is deposited on the supporting substrate 74. The respective process is shown as a step S206 in the process flow 200 as shown in FIG. 9. In accordance with some embodiments, the dielectric buffer layer 76 is deposited on the semiconductor substrate 74 first. The dielectric buffer layer 76 may comprise silicon oxide or other materials. The stress compensation layer 78 is deposited on the dielectric buffer layer 76. The stress compensation layer 78 has an internal stress, and is used to apply a stress to the overlying structure, so that the warpage of the resulting reconstructed wafer 170′ is reduced. In accordance with some embodiments, the stress compensation layer 78 comprises silicon nitride. The stress in the stress compensation layer 78 may be adjusted by adjusting the process condition of the deposition process.

FIG. 8D illustrates a thinning process of the dielectric layer 28 of the photonic wafer 20′, so that the metal via 34 is exposed. The respective process is shown as a step S208 in the process flow 200 as shown in FIG. 9. The thinning process may be performed through a CMP process or a mechanical grinding process.

FIG. 8E illustrates the deposition of a mask layer 80. The respective process is shown as a step S210 in the process flow 200 as shown in FIG. 9. The formation process may include a deposition process. In accordance with some embodiments, the mask layer 80 is formed of or comprises silicon nitride, silicon carbide, or the like.

Next, as shown in FIG. 8F, an etching process is performed to pattern the mask layer 80, with a portion of mask layer 80 being left to cover the metal via 34 to act as an etch stop layer for subsequent processes. The respective process is shown as a step S212 in the process flow 200 as shown in FIG. 9.

FIG. 8G illustrates the formation of a buffer dielectric layer 82 and a hard mask 84, which are formed through deposition processes. The respective process is shown as a step S214 in the process flow 200 as shown in FIG. 9. In accordance with some embodiments, the buffer dielectric layer 82 comprises silicon oxide, and the hard mask 84 comprises silicon nitride, while other dielectric materials may also be used.

Referring to FIG. 8H, the hard mask 84 and the buffer dielectric layer 82 are etched to form an opening 86. The respective process is shown as a step S216 in the process flow 200 as shown in FIG. 9. The etching may be stopped on the mask layer 80, so that in subsequent processes, the mask layer 80 may protect the underlying metal via 34 from being damaged and oxidized.

FIG. 8I illustrates a first etching process of a two-photo-two-etching (2P2E) process in order to groove the reconstructed wafer 170′. The respective process is shown as a step S218 in the process flow 200 as shown in FIG. 9. In accordance with some embodiments, an etching mask 88A is formed and patterned. The etching mask 88A may comprise a photoresist. A first etching process 92A is then performed to form trenches 90A in the reconstructed wafer 170′. When viewed in a top view of the reconstructed wafer 170′, the trenches 90A may be formed to have a grid pattern including a plurality trenches having lengthwise directions in a first direction, and a plurality of trenches having lengthwise directions in a second direction perpendicular to the first direction. The trenches 90A are formed in the scribe lines of the respective reconstructed wafer 170′, which scribe lines are used for the subsequent sawing processes. After the first etching process 92A, the etching mask 88A is removed.

As shown in FIG. 8I, the bottoms of the trenches 90A are at a top surface of the EIC die 54, with the trenches 90A extending into the dielectric regions 68. In accordance with alternative embodiments, the bottoms of the trenches 90A may be at a higher level such as lower than the bottom of the bulk dielectric region 44 but higher than the gap-fill regions 69. In accordance with yet alternative embodiments, the bottoms of the trenches 90A may be at an intermediate level between a top surface and a bottom surface of the bulk dielectric region 44. The corresponding levels of the possible positions of trenches 90A are shown using dashed lines 91.

FIG. 8J illustrates a second etching process of the 2P2E process in order to groove the reconstructed wafer 170′. The respective process is shown as a step S220 in the process flow 200 as shown in FIG. 9. In accordance with some embodiments, an etching mask 88B is formed and patterned. The etching mask 88B may comprise a photoresist. The opening in the etching mask 88B is narrower than the trenches 90A. Accordingly, some portions of the etching mask 88B are filled into the trenches 90A. A second etching process 92B is then performed to form the trenches 90B in the reconstructed wafer 170′. When viewed in a top view of the reconstructed wafer 170′, the trenches 90B may also be formed to have a grid pattern.

In accordance with some embodiments, the trenches 90B penetrate through the dielectric regions 68, and may stop on the supporting substrate 74 or the bonding layer 72. After the second etching process 92B, the etching mask 88B is removed, for example, through an ashing process. The trenches 90A and 90B may be collectively referred to as trenches 90. The resulting trenches 90 are shown in FIG. 8K.

As shown in FIG. 8K, the reconstructed wafer 170′ include surfaces 93, which include sidewalls (also referred to as facets) 93A and 93B, and a transition top surface 93C connecting the sidewalls 93A to the respectively underlying sidewalls 93B. The sidewalls 93A and the transition top surfaces 93C are formed by the first etching process, and the sidewalls 93B are formed by the second etching process.

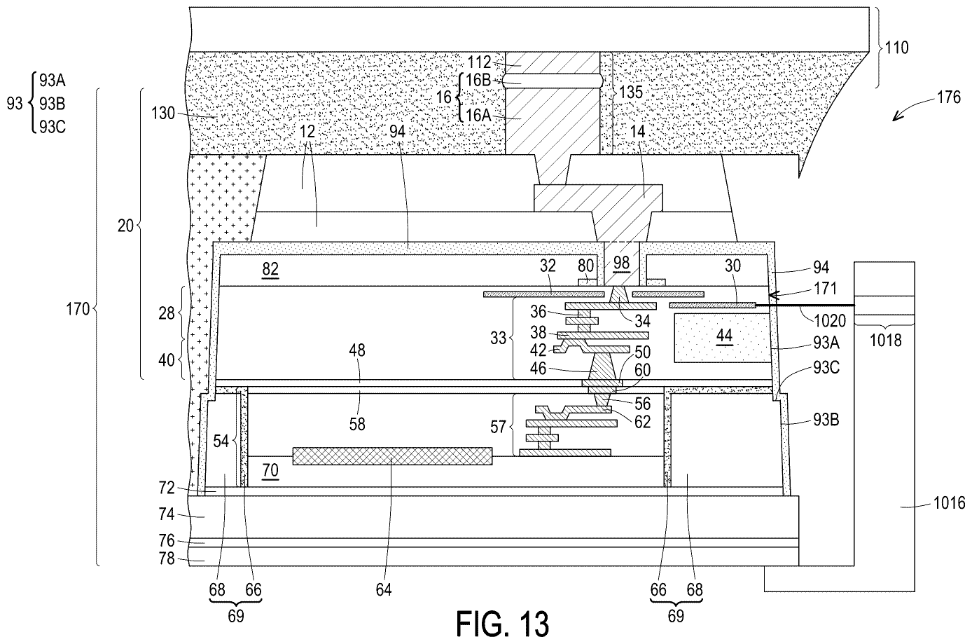

It is appreciated that by forming the trenches 90 through two etching processes, the first etching process, during which the sidewalls 93A are formed may have a reduced duration. When the resulting photonic package is used, as shown in FIG. 13, the optical signal will pass through the sidewall 93A to reach the waveguide 30. Accordingly, the smoothness of the sidewall 93A affects the scattering of the optical signal, and a smoother sidewall 93 results in less scattering, and lower loss in the optical signal.

Since the longer the etching duration is, the rougher the sidewalls 93A will be, by forming the trenches 90 through two etching processes rather than one etching process, the first etching process may be performed in a shorter time. Accordingly, adopting two etching processes results in the sidewalls 93A to be smoother.

In a subsequent process, an etching process is performed to remove the exposed portion of the mask layer 80. The respective process is shown as a step S222 in the process flow 200 as shown in FIG. 9. The metal via 34 is thus exposed.

Referring to FIG. 8L, a protection layer 94 is formed. The respective process is shown as a step S224 in the process flow 200 as shown in FIG. 9. In accordance with some embodiments, the protection layer 94 comprises a same material as that of the hard mask 84 (FIG. 8K) such as silicon nitride, silicon oxynitride, silicon carbide, or the like. Accordingly, the hard mask 84 is shown as being a part of the protection layer 94, and is no longer illustrated. In accordance with alternative embodiments, the hard mask 84 may be distinguishable from the protection layer 94. In accordance with some embodiments, the protection layer 94 is deposited using a conformal deposition process such as ALD, CVD, or the like.

FIG. 8M illustrates the lateral removal process for removing the lateral portions of the protection layer 94, for example, through an anisotropic etching process. The respective process is shown as a step S226 in the process flow 200 as shown in FIG. 9. In accordance with some embodiments, the lateral portions of the protection layer 94 at the bottom of the trenches 90B may be fully removed, or may be thinned. Furthermore, the lateral portions of the protection layer 94 on the transition top surface 93C may be removed or thinned. The regions 96 are illustrated to show where the protection layer 94 may be either fully removed, or thinned but not fully removed.

FIG. 8N illustrates the formation of upper features of the reconstructed wafer 170′. The respective process is shown as a step S228 in the process flow 200 as shown in FIG. 9. A dielectric layers 12 are formed over the protection layer 94. In accordance with some embodiments, the dielectric layers 12 may be formed of or comprises organic materials such as polymers. For example, the dielectric layers 12 may be formed of or comprise polyimide, PBO, or the like.

Conductive features such as metal via 98, RDLs 14 and electrical connectors 16 are formed to electrically connect to the metal vias 34 and the underlying interconnect structure, and to integrated circuit devices 64. In accordance with some embodiments, the electrical connectors 16 include metal pillars 16A and solder regions 16B.

Subsequently, a sacrificial material 172 is formed to fill into the trenches 90. The respective process is shown as a step S230 in the process flow 200 as shown in FIG. 9. In some embodiments, the sacrificial material 172 may include a polymer material such as photoresist, and may be formed by spin coating or the like. The sacrificial material 172 can prevent the subsequently formed underfill and encapsulant from covering the sidewalls 93A and 93B (especially the sidewall 93A) and blocking the transmission of light. As shown in FIG. 8O, a top surface of the sacrificial material 172 is at a top surface of the dielectric layers 12. In accordance with alternative embodiments, the top surface of the sacrificial material 172 may be at a lower level such as lower than the top surface of the dielectric layers 12 but higher than the top surface of the dielectric layers 28. That is, the top surface of the sacrificial material 172 may be at an intermediate level between the top surface of the dielectric layers 12 and the top surface of the dielectric layers 28.

Although FIG. 8O illustrates the sacrificial material 172 filled into the trenches 90 at opposite sides of the reconstructed wafer 170′, the embodiments of the present disclosure are not limited thereto. In some other embodiments, the sacrificial material 172 may be only filled in the trench 90 adjacent to the sidewall 93A (or light transmission surface).

After forming the sacrificial material 172, a sawing process (also referred to as a singulation process) is performed to saw the reconstructed wafer 170′ and to form a plurality of photonic engines 170. The respective process is shown as a step S232 in the process flow 200 as shown in FIG. 9. The plurality of photonic engines 170 are identical, and each may include a PIC die 20, an EIC die 54, and a supporting substrate 74, which is sawed from the wafer-level supporting substrate 74.

In accordance with some embodiments, the kerves of the sawing process pass through the trenches 90. The surfaces 93 and the protection layer 94 thereon are not damaged. FIG. 8P illustrates one of the photonic engines 170 in accordance with some embodiments. Due to the sawing of the supporting substrate 74, an edge 74E (FIG. 8P) is formed. The supporting substrate 74 extends laterally beyond the sidewalls 93A and 93B, and the edge 74E is substantially aligned with an edge 172E of the sacrificial material 172. In the present embodiment, the photonic engine 170 may include the recess 175 having a stepped surface, and the sacrificial material 172 may be filled into the recess 175 to prevent the subsequently formed underfill and encapsulant from covering the sidewalls 93A and 93B (especially the sidewall 93A). Although FIG. 8P illustrates one of the photonic engines 170 has the sidewalls (also referred to as facets) 93A and 93B at opposite sides, the embodiments of the present disclosure are not limited thereto. In some other embodiments, the photonic engine 170 may have the sidewalls (also referred to as facets) 93A and 93B at one side adjacent to the light transmission surface, as shown in FIG. 2. That is, the recess 175 or the sidewalls (also referred to as facets) 93A and 93B is only at the edge of the initial structure 10 for edge coupling.

Referring back to FIG. 2, after bonding the integrated circuit components 150, 160 and 170 onto the interposer 140, the underfill layer 130 is formed. The respective process is shown as a step S104 in the process flow 100 as shown in FIG. 1. In some embodiments, the underfill layer 130 is formed to laterally encapsulate the conductive connectors 135 to protect the conductive connectors 135 from thermal and mechanical stresses. In addition, the underfill layer 130 may fill into the gaps between the integrated circuit components 150, 160 and 170, and extend along a portion of the sidewall of the integrated circuit component 160.

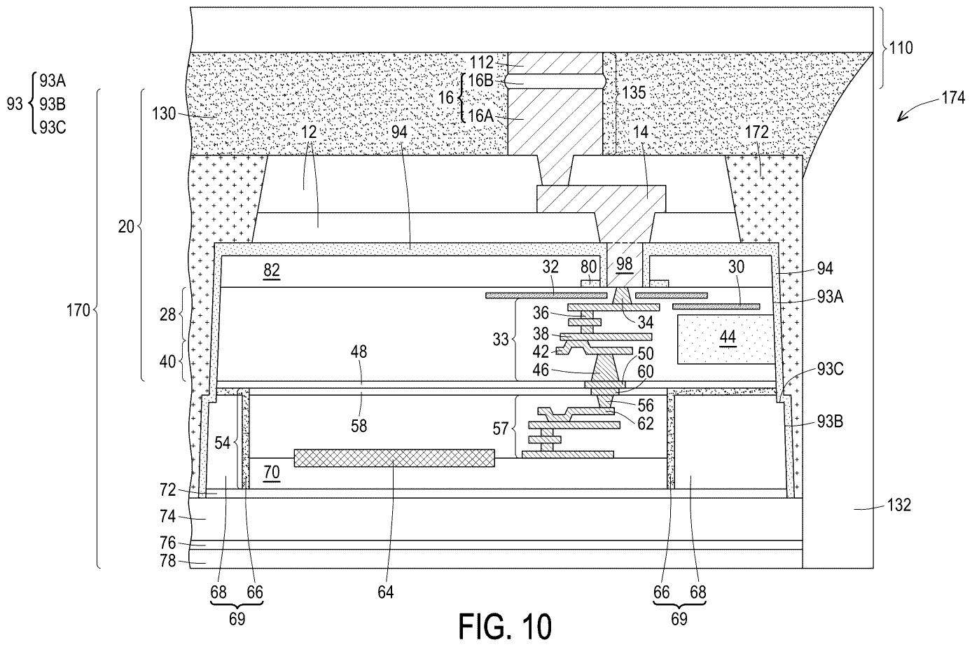

FIG. 10 illustrates an enlarged cross-sectional view of a region 174 of FIG. 2 in accordance with some embodiments. Specifically, the underfill layer 130 may extend along a portion of the sidewall of the integrated circuit component 170 and be in physical contact with a portion of the edge 172E of the sacrificial material 172. That is, the sidewalls 93A and 93B (especially the sidewall 93A) is physically separated from the underfill layer 130 by the sacrificial material 172. In such embodiment, the underfill layer 130 is not in direct contact with the sidewalls 93A and 93B (especially the sidewall 93A). In some alternative embodiments, the underfill layer 130 may extend between the first redistribution structure 110 and the integrated circuit component 170 without climbing on the edge 172E of the sacrificial material 172.

After forming the underfill layer 130, the encapsulant 132 is formed to laterally encapsulate the underfill layer 130 and the integrated circuit components 150, 160 and 170. The respective process is shown as a step S106 in the process flow 100 as shown in FIG. 1. Specifically, as shown in FIG. 10, the encapsulant 132 may extend along and is in physical contact with the sidewall of the underfill layer 130, the edge 172E of the sacrificial material 172, and the edge 74E of the supporting substrate 74. As shown in FIG. 10, the sidewalls 93A and 93B (especially the sidewall 93A) is physically separated from the encapsulant 132 by the sacrificial material 172. That is, the encapsulant 132 is not in direct contact with the sidewalls 93A and 93B (especially the sidewall 93A).

In some embodiments, the encapsulant 132 may be a molding compound, epoxy, or the like. The encapsulant 132 may not include fillers therein. The encapsulant 132 may be applied by compression molding, transfer molding, or the like, and is formed over the first redistribution structure 110 so that the integrated circuit components 150, 160 and 170 are buried or covered. The encapsulant 132 may be applied in liquid or semi-liquid form and then subsequently cured. The encapsulant 132 may be thinned to expose the integrated circuit components 150, 160 and 170. The thinning process may be a grinding process, a CMP, an etch-back, combinations thereof, or the like. After the thinning process, top surfaces of the integrated circuit components 150, 160 and 170, and the encapsulant 132 are coplanar (within process variations), so that they are level with one another. The thinning is performed until a desired amount of the integrated circuit components 150, 160 and 170, and/or the encapsulant 132 has been removed. In the present embodiment, the sacrificial material 172 can protect the underfill layer 130 from the damage during the thinning process.

Moreover, the initial structure 10 further includes a plurality of conductive connectors 125 formed on the second redistribution structure 120 to attached the initial structure 10 to a carrier 180.

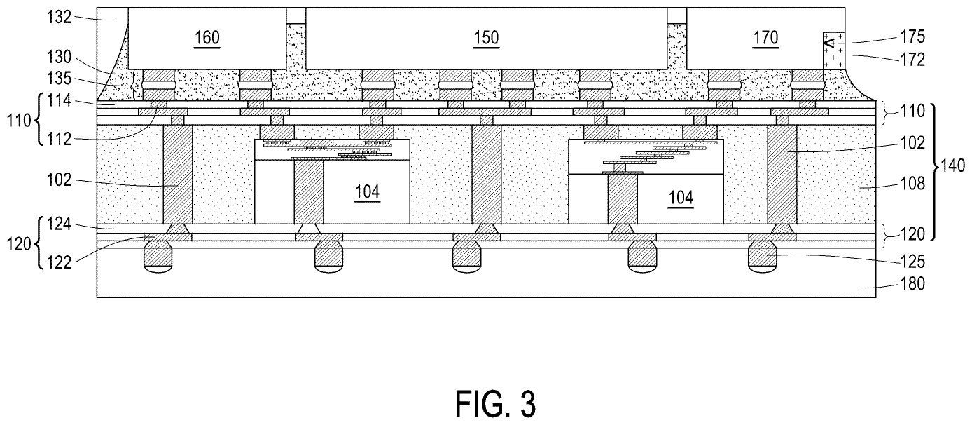

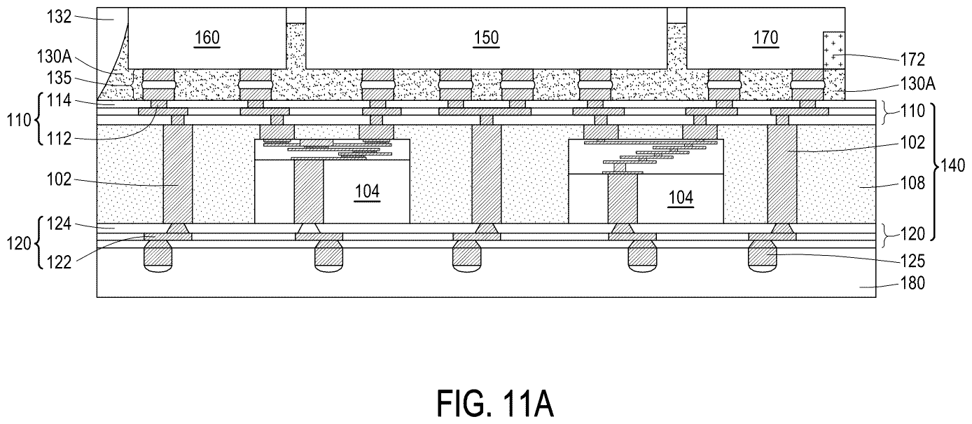

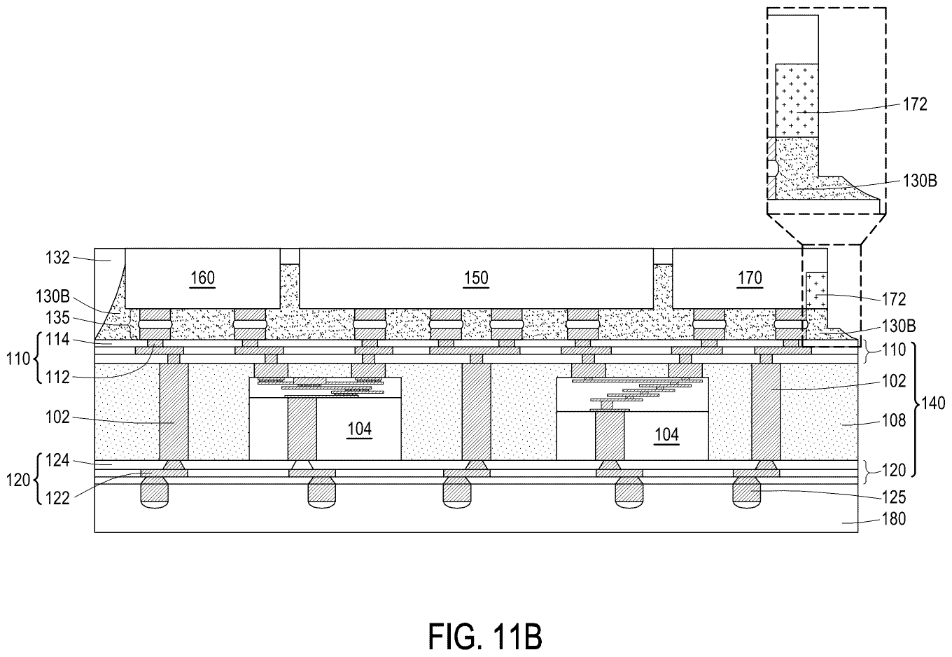

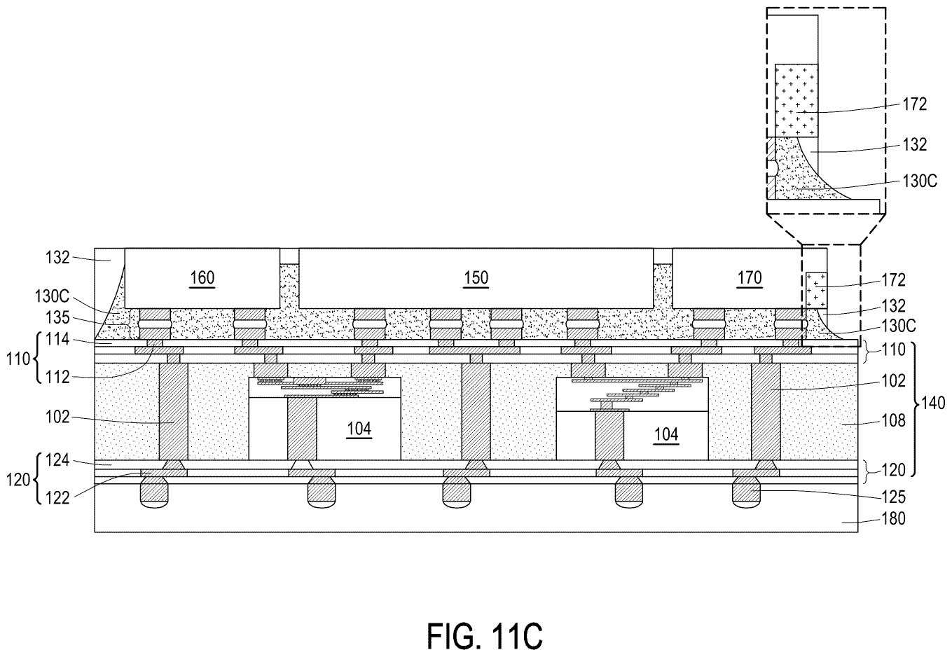

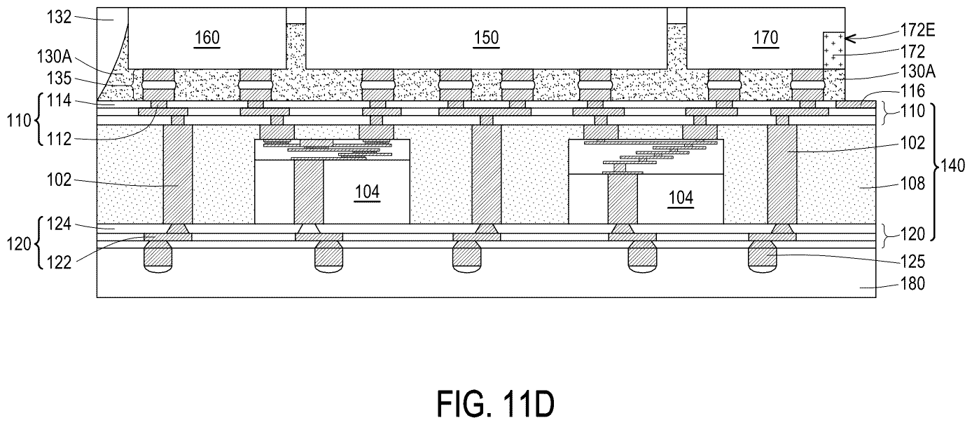

Referring to FIG. 3, a portion of the encapsulant 132 is removed to expose the sacrificial material 172 within the recess 175 of the integrated circuit component 170. The respective process is shown as a step S108 in the process flow 100 as shown in FIG. 1. In some embodiments, a laser trimming process is performed on the encapsulant 132 to at least remove the portion of the encapsulant 132 covering the sacrificial material 172, thereby exposing the sacrificial material 172. In this case, the underfill layer 130 is not removed or only a small amount of the underfill layer 130 is removed, so that the underfill layer 130 still retains the curved sidewall. In some alternative embodiments, a portion of the underfill layer 130 is removed to expose the top surface of the first redistribution structure 110. In such embodiment, the trimmed underfill layer 130A has a sidewall substantially aligned with a sidewall of the sacrificial material 172 so that the trimmed underfill layer 130A a rectangular cross-sectional shape, as shown in FIG. 11A. In some other embodiments, a portion of the underfill layer 130 is partially removed by the laser trimming process. In such embodiment, the trimmed underfill layer 130B has a combination of a vertical sidewall and a curved sidewall, as shown in FIG. 11B. In some other embodiments, after performing the laser trimming process, a portion of the encapsulant 132 may be sandwiched between the sacrificial material 172 and the trimmed underfill layer 130C, as shown in FIG. 11C. In some yet embodiments, a dummy metal 116 may be formed in the first redistribution structure 110 and directly under the edge 172E of the sacrificial material 172. In this case, the dummy metal 116 may be referred to as a trim stop layer in the laser trimming process, so that the first redistribution structure 110 is protected from damage during the laser trimming process.

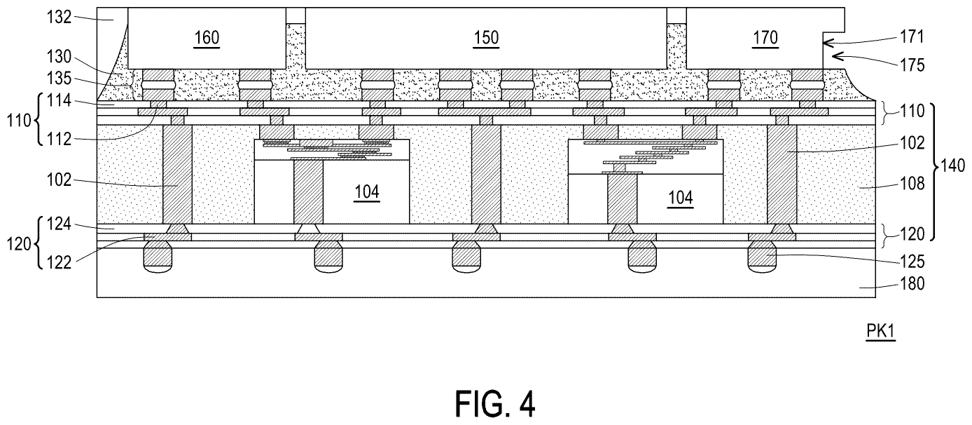

Referring to FIG. 4, the sacrificial material 172 is removed to expose the recess 175 of the integrated circuit component 170. The respective process is shown as a step S110 in the process flow 100 as shown in FIG. 1. In some embodiments, the sacrificial material 172 is removed by any acceptable etching process, such as a wet etching process or the like. The etching process is selective to the sacrificial material 172 (e.g., selectively etches the material of the sacrificial material 172 at a faster rate than the materials of the underfill layer 130, the encapsulant 132, and the protection layer 94 (as shown in FIG. 10). In the present embodiment, the sacrificial material 172 is completely removed to expose a light transmission surface 171 of the photonic engine 170, thereby accomplishing a package structure PK1. Herein, the term “light transmission surface” is referred to a region of the sidewall 93A adjacent to the waveguide 30, so that the optical signals may passes through the sidewall 93A to reach the waveguide 30.

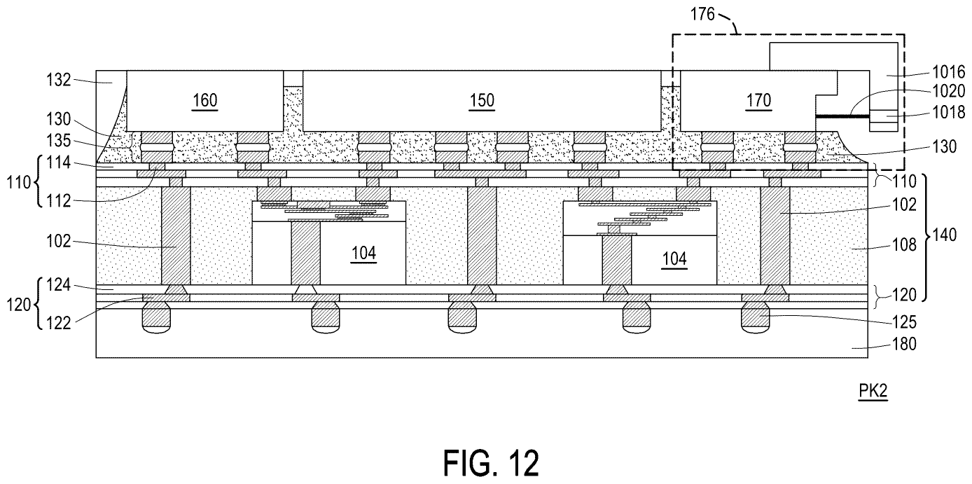

FIG. 12 illustrates a cross-sectional view of a package structure in accordance with some embodiments.

Referring to FIG. 12, a Fiber Assembly Unit (FAU) 1016 may be attached to the photonic engine 170, thereby accomplishing a package structure PK2. FIG. 13 illustrates an enlarged cross-sectional view of a region 176 of FIG. 12 in accordance with some embodiments. Specifically, an optical fiber 1018 may be aligned to the waveguide 30 through edge coupling. A laser beam 1020 may be projected out of the optical fiber 1018, and projected into the waveguide 30. The laser beam 1020 passes through the sidewall 93A to reach the waveguide 30, which may optically couple the optical signals into the waveguide 32. The optical signals carried by the laser beam 1020 are processed by the PIC die 20 and the EIC die 54. The optical signals may alternatively be converted to electrical signal by the PIC die 20, and the electrical signals are transferred to the EIC die 54.

As shown in FIG. 13, the optical signals pass through the light transmission surface 171 to reach the waveguide 30 without any underfill and/or molding residue blocking the light transmission. In such embodiment, the loss of the optical signal can be reduced, and the signal latency between components can be reduced, thereby enhancing the performance of the package structure PK2.

In addition, the optical signals pass through the sidewall 93A. Since sidewall 93A is smoother due to that the first etching process 92A (FIG. 8I) takes shorter time, the loss of the optical signal at sidewall 93A is reduced. The ratio of a height H1 of sidewall 93A and a height H2 of sidewall 93B are adjusted to achieve good results. For example, if the value of the height H1 (FIG. 8P) is too big, the first etching process is too long, and the sidewall 93A will be rougher. This defeats the purpose of adopting two etching processes. If the value of the height H1 is too small, and the bottom of the trenches 90A are higher than the level of the waveguide 30, the optical signal will have to pass the sidewall 93B rather than sidewall 93A. Since the height H2 of the sidewall 93B is big in these embodiments, the sidewall 93B is also rough. In accordance with some embodiments, the height H1 may be small than the height H2.

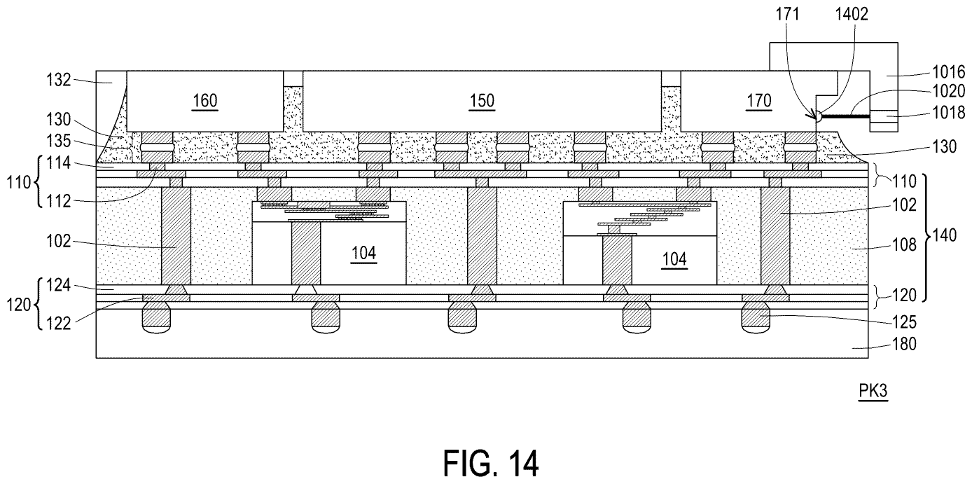

FIG. 14 illustrates a cross-sectional view of a package structure in accordance with some alternative embodiments.

Referring to FIG. 14, a micro lens 1402 may be optionally attached to the photonic engine 170, thereby accomplishing a package structure PK3. Specifically, the optional micro lens 1402 may be disposed on the light transmission surface 171 of the photonic engine 170 to improve the optical coupling between the waveguide 30 and the optical fiber 1018.

According to some embodiments, a method of forming a package structure includes: bonding a first integrated circuit component onto an interposer, wherein the first integrated circuit component has a recess filled with a sacrificial material therein; forming an underfill layer between the interposer and the first integrated circuit component; forming an encapsulant on the interposer to laterally encapsulate the underfill layer and the first integrated circuit component; removing a portion of the encapsulant to expose the sacrificial material; and removing the sacrificial material to expose the recess of the first integrated circuit component.

In some embodiments, the encapsulant is in direct contact with the underfill layer and the sacrificial material, and the underfill layer laterally surrounds the first integrated circuit component. In some embodiments, the sacrificial material comprises a polymer material. In some embodiments, the recess has a stepped surface. In some embodiments, the removing the portion of the encapsulant comprises: performing a laser trimming process on the encapsulant to remove the portion of the encapsulant covering the sacrificial material. In some embodiments, the laser trimming process further removes a portion of the underfill layer protruding from an edge of the sacrificial material, so that the underfill layer has a sidewall substantially aligned with a sidewall of the sacrificial material. In some embodiments, further comprising: attaching a Fiber Assembly Unit (FAU) to the first integrated circuit component, wherein an optical fiber of the FAU is aligned to the first integrated circuit component through edge coupling. In some embodiments, further comprising: attaching a micro lens to the first integrated circuit component, so that the micro lens is laterally between the first integrated circuit component and the FAU. In some embodiments, the first integrated circuit component comprises a photonic die, and the photonic die is configured to convert an optical signal to an electronic signal. In some embodiments, further comprising: bonding a second integrated circuit component onto the interposer and aside the first integrated circuit component, wherein the underfill layer is further filled into a gap between the first integrated circuit component and the second integrated circuit component.

According to some embodiments, a package structure includes a first integrated circuit component disposed on an interposer, wherein the first integrated circuit component has a recess; a plurality of conductive connectors disposed between the first integrated circuit component and the interposer; an underfill layer laterally surrounding the plurality of conductive connectors and formed between the first integrated circuit component and the interposer; and a Fiber Assembly Unit (FAU) attached to the first integrated circuit component, wherein the FAU comprises an optical fiber aligned to the first integrated circuit component through the recess.

In some embodiments, the recess has a stepped surface, and the recess is free of the underfill layer. In some embodiments, further comprising an encapsulant on the interposer, wherein the recess is free of the encapsulant. In some embodiments, further comprising a micro lens attached to the first integrated circuit component, so that the micro lens is laterally between the first integrated circuit component and the FAU. In some embodiments, the first integrated circuit component comprises a photonic die, and the photonic die is configured to convert an optical signal to an electronic signal. In some embodiments, further comprising a second integrated circuit component bonded onto the interposer and aside the first integrated circuit component, wherein the underfill layer is formed between the first integrated circuit component and the second integrated circuit component.

According to some embodiments, a package structure includes: a photonic component comprising: a supporting substrate; an electronic die bonded to the supporting substrate; and a photonic die over the electronic die, wherein the supporting substrate has an edge portion protruding from a first edge of the photonic die and a second edge of the electronic die; an interposer formed on the photonic component; and an underfill layer formed between the photonic component and the interposer, wherein a portion of the first edge of the photonic die is free of the underfill layer.

In some embodiments, further comprising a Fiber Assembly Unit (FAU) attached to the photonic component, wherein an optical fiber of the FAU is aligned to the photonic component through the recess without the underfill layer. In some embodiments, further comprising a micro lens attached to the photonic component, so that the micro lens is laterally between the photonic component and the FAU. In some embodiments, the photonic component further comprises: a gap-fill region encircling the electronic die, wherein the gap-fill region comprises a first sidewall and the photonic die comprises a second sidewall; and a protection layer overlying the first sidewall and the second sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a package structure, comprising:
bonding a first integrated circuit component onto an interposer, wherein the first integrated circuit component has a recess filled with a sacrificial material therein;
forming an underfill layer between the interposer and the first integrated circuit component;
forming an encapsulant on the interposer to laterally encapsulate the underfill layer and the first integrated circuit component;
removing a portion of the encapsulant to expose the sacrificial material; and
removing the sacrificial material to expose the recess of the first integrated circuit component.

2. The method of claim 1, wherein the encapsulant is in direct contact with the underfill layer and the sacrificial material, and the underfill layer laterally surrounds the first integrated circuit component.

3. The method of claim 1, wherein the sacrificial material comprises a polymer material.

4. The method of claim 1, wherein the recess has a stepped surface.

5. The method of claim 1, wherein the removing the portion of the encapsulant comprises:
performing a laser trimming process on the encapsulant to remove the portion of the encapsulant covering the sacrificial material.

6. The method of claim 5, wherein the laser trimming process further removes a portion of the underfill layer protruding from an edge of the sacrificial material, so that the underfill layer has a sidewall substantially aligned with a sidewall of the sacrificial material.

7. The method of claim 1, further comprising:
attaching a Fiber Assembly Unit (FAU) to the first integrated circuit component, wherein an optical fiber of the FAU is aligned to the first integrated circuit component through edge coupling.

8. The method of claim 7, further comprising:
attaching a micro lens to the first integrated circuit component, so that the micro lens is laterally between the first integrated circuit component and the FAU.

9. The method of claim 1, wherein the first integrated circuit component comprises a photonic die, and the photonic die is configured to convert an optical signal to an electronic signal.

10. The method of claim 1, further comprising:
bonding a second integrated circuit component onto the interposer and aside the first integrated circuit component, wherein the underfill layer is further filled into a gap between the first integrated circuit component and the second integrated circuit component.

11. A package structure, comprising:
a first integrated circuit component disposed on an interposer, wherein the first integrated circuit component has a recess;
a plurality of conductive connectors disposed between the first integrated circuit component and the interposer;
an underfill layer laterally surrounding the plurality of conductive connectors and formed between the first integrated circuit component and the interposer; and
a Fiber Assembly Unit (FAU) attached to the first integrated circuit component, wherein the FAU comprises an optical fiber aligned to the first integrated circuit component through the recess.

12. The package structure of claim 11, wherein the recess has a stepped surface, and the recess is free of the underfill layer.

13. The package structure of claim 11, further comprising an encapsulant on the interposer, wherein the recess is free of the encapsulant.

14. The package structure of claim 11, further comprising a micro lens attached to the first integrated circuit component, so that the micro lens is laterally between the first integrated circuit component and the FAU.

15. The package structure of claim 11, wherein the first integrated circuit component comprises a photonic die, and the photonic die is configured to convert an optical signal to an electronic signal.

16. The package structure of claim 11, further comprising a second integrated circuit component bonded onto the interposer and aside the first integrated circuit component, wherein the underfill layer is formed between the first integrated circuit component and the second integrated circuit component.

17. A package structure, comprising:
a photonic component comprising:
a supporting substrate;
an electronic die bonded to the supporting substrate; and
a photonic die over the electronic die, wherein the supporting substrate has an edge portion protruding from a first edge of the photonic die and a second edge of the electronic die;
an interposer formed on the photonic component; and
an underfill layer formed between the photonic component and the interposer, wherein a portion of the first edge of the photonic die is free of the underfill layer.

18. The package structure of claim 17, further comprising a Fiber Assembly Unit (FAU) attached to the photonic component, wherein an optical fiber of the FAU is aligned to the photonic component through the recess without the underfill layer.

19. The package structure of claim 18, further comprising a micro lens attached to the photonic component, so that the micro lens is laterally between the photonic component and the FAU.

20. The package structure of claim 17, wherein the photonic component further comprises:
a gap-fill region encircling the electronic die, wherein the gap-fill region comprises a first sidewall and the photonic die comprises a second sidewall; and
a protection layer overlying the first sidewall and the second sidewall.
